(19) United States
(12) Patent Application Publication
(10) Pub. No.: US 2005/0012115 A1
(43) Pub. Date: Jan. 20, 2005

(54) Ion sensitive field effect transistor and method for producing an ion sensitive field effect transistor

(76) Inventors: Heinrich Grueger, Dresden (DE); Christian Kunath, Dresden (DE)

Correspondence Address: GLENN PATENT GROUP, 3475 EDISON WAY, SUITE L, MENLO PARK, CA, 94025, US

(21) Appl. No.: 10/917,049

(22) Filed: Aug. 11, 2004

Related U.S. Application Data
(63) Continuation of application No. PCT/EP02/01410, filed on Feb. 11, 2002.

(51) Int. Cl. H01L 31/0328

(52) U.S. Cl. 257/192

(57) ABSTRACT

The invention relates to an ion-sensitive field effect transistor, comprising a gate (36) consisting of carbon nitride. The carbon nitride gate (36) is highly resistant to aggressive substances to be measured and also exhibits good adhesive properties. In addition, the ion-sensitive field effect transistor has high long-term stability and negligible drift. Said ion-sensitive field effect transistor can be produced in a method that uses CMOS-compatible planar technology.

### CROSS-REFERENCE TO RELATED APPLICATION

This application is a continuation of copending International Application No. PCT/EP02/01410, filed Feb. 11, 2002, which designated the United States and was not published in English.

### BACKGROUND OF THE INVENTION

1. Field of the Invention

The present invention relates to ion sensitive field effect transistors as well as to a method for producing the same.

2. Description of the Prior Art

Ion sensitive field effect transistors (ISFET) serve as detection elements, for example during measuring a pH value, measuring ions or special substance concentrations. Fields of application for ion sensitive field effect transistors are process measuring technique, analytical chemistry or environmental technology, wherein measurements are typically performed in aqueous solutions or organic mixtures.

Prior to the usage of semiconductor detection apparatuses, glass electrodes were exclusively used for electric transducers for measuring pH values. In many aggressive media, glass electrodes can be operated in a stable way, but their stability is restricted in strong alkali solutions. Further, a usage of glass electrodes in hydrofluoric acid is not possible. Setting the measurement value takes place very slowly. Glass electrodes require a high proportion of manual labor in the production, which is why the same are expensive. Further, the field of application of glass electrodes is limited since they generate splinters when breaking. For example, usage of glass electrodes in food technology is not feasible, since the splinters resulting from breakage are dangerous foreign bodies in food. Glass electrodes are preferably used in process measuring technology.

In contrary to glass electrodes, the usage of ion sensitive field effect transistors represents a break-proof alternative for ion sensitive measuring of measurement liquids, so that the same can be used in areas where failsafe additional requirements are required, such as in food technology.

Typically, when measuring with an ion sensitive field effect transistor, its gate is brought into contact with the measurement fluid. A change of potential at the gate, which is generated by a change of ion concentration in the measurement fluid, leads to a measurement signal. Since the gate comes directly into contact with the measurement liquid during measuring, gate materials, which are resistive against the respective measurement media for long periods, will have to be utilized for the usage in aggressive media if a high longtime stability and/or a low drift is required.

For some time, ion sensitive field effect transistors with Si₃N₄ as gate material are used. These are only suitable in a limited way for usage with the above-mentioned requirements, since the gate of Si₃N₄ is subject to a high drift and has a low longtime stability. Further, the ion sensitive field effect transistors with a gate of Si₃N₄ cannot be used in aggressive media over longer periods.

In comparison to Si₃N₄ as gate material, improved characteristics of ion sensitive field effect transistors can be obtained by using metal oxides as gate material. However, ion sensitive field effect transistors with a metal oxide gate have the disadvantage that they do not have sufficient resistance against basic solutions with high temperatures and against hydrofluoric acid.

In later developments, ion sensitive field effect transistors are used, where amorphous diamond-like carbon (DLC) is used as gate material, which has a high proportion of sp³ hybridized carbon bonds. Such systems have a very high chemical resistance, particularly in hydrofluoric acid. However, one disadvantage of using amorphous diamond-like carbon, is that layers of this material have a high internal stress, which can reduce the layer adhesion and can lead to peeling off of the layers and consequently to a destruction of the ion sensitive field effect transistor. Thus, these ion sensitive field effect transistors are not suitable for long-term usage in all fields of application.

### SUMMARY OF THE INVENTION

It is the object of the present invention to provide a cost effective, secure and long term stable ion sensitive field effect transistor and a method for producing same.

In accordance with a first aspect, the present invention provides an ion sensitive field effect transistor having a gate of carbon nitride.

In accordance with a second aspect, the present invention provides a method for producing an ion sensitive field effect transistor, comprising providing a substrate with a source region and a drain region; and forming a gate of carbon nitride on the substrate.

The present invention provides an ion sensitive field effect transistor with a gate consisting of a material, which has stability in aggressive media comparable to the DLC, good drift characteristics as well as a better adhesion strength on the base due to low layer stress. Further, the gate material can be produced in large batches in semiconductor production processes. The environmental compatibility of the gate material is ensured.

The present invention is based on the knowledge that an ion sensitive field effect transistor with high stability is achieved by using carbon nitride (CNₓ) as gate material. By introducing nitrogen atoms into a carbon layer, mechanical internal stresses are reduced, whereby a good adhesion capability of the inventive gate material is achieved with a good chemical resistance against aggressive media.

It is an advantage of the present invention that by changing the nitrogen content during production, the mechanical and chemical characteristics of the gate material can be adjusted, whereby the ion sensitive field effect transistor can be adjusted with regard to an intended field of application, such as sensitivity.

It is another advantage of the present invention that the inventive ion sensitive field effect transistor can be operated in a secure way, i.e. without the danger of forming splinters during breakage, whereby it is suitable for fields of application, which require a high operational safety, such as for food technology.

Further, the inventive ion sensitive field effect transistor can be produced in CMOS compatible planar technology in an inexpensive way, wherein further circuit elements integrated on the chip, which are, for example, used for detecting measurement data, can be generated together with the ion sensitive field effect transistor.

According to a preferred embodiment of the present invention, an ion sensitive field effect transistor comprises a substrate, on the surface of which a gate of carbon nitride is formed above a channel region by reactive sputtering. Preferably, the gate of carbon nitride has a nitrogen content of 18-30 at % to obtain both a good adhesion of the substrate as well as a good chemical protection.

In further embodiments, the inventive gate can comprise a layer structure, which has several layers of carbon nitride with different nitrogen content. For forming a good adhesion, the lower layer of the layer structure, which is arranged adjacent to the channel region, has a high nitrogen proportion, and the nitrogen proportion of the layer decreases with increasing distance of the channel region, so that an outer layer has a high chemical resistance due to the low nitrogen proportion.

In a further embodiment, the inventive gate layer of carbon nitride can comprise a concentration gradient, wherein the concentration of the nitrogen decreases starting from a surface of the layer, which is arranged adjacent to the channel region, with increasing distance of the channel region, so that the outer surface of the layer facing away from the channel region, which comes into contact with a measurement fluid during measuring, has a low nitrogen proportion for achieving a high chemical resistance.

### BRIEF DESCRIPTION OF THE DRAWINGS

These and other objects and features of the present invention will become clear from the following description taken in conjunction with the accompanying drawing, in which:

FIG. 1 is a cross-section representation of an ion sensitive field effect transistor according to a preferred embodiment of the present invention.

### DESCRIPTION OF THE PREFERRED EMBODIMENTS

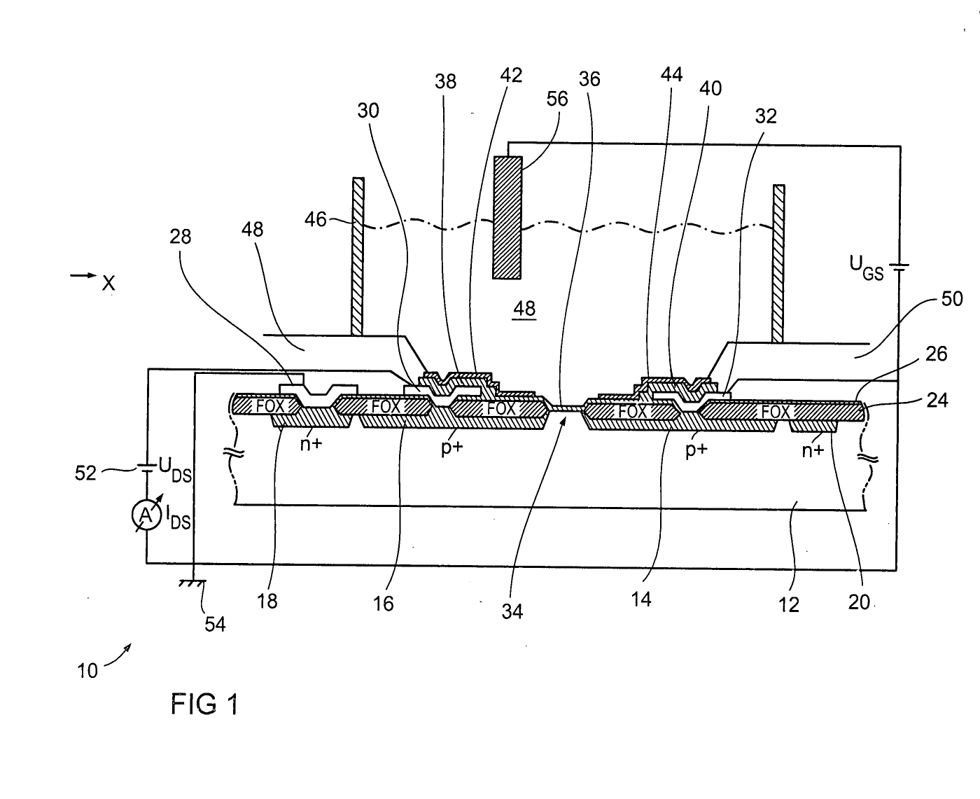

In FIG. 1, a cross-section representation of an ion sensitive field effect transistor (FET) 10 is shown. The FET 10 comprises a semiconductor substrate 12, such as a silicon substrate. A p⁺ source region 14 and a p⁺ drain region 16 are formed in the substrate 12. Further, a first substrate terminal region 18 and a second substrate terminal 20 are formed in the substrate 12, which comprise n⁺ regions (ohmic contacts). Therefore, the substrate can be a combination of a carrier substrate and an epitaxial layer arranged thereon, wherein the active regions of the device are formed.

A field oxide layer 24 is formed on a surface of the substrate 12. A further isolating layer 26 is formed on the field oxide layer 24.

Further, the FET 10 comprises a terminal 28, e.g. of aluminum, which extends through the field oxide layer 24 and the isolating layer 26 and is connected to a first substrate terminal region 18. Further, the FET 10 comprises a drain contact (a drain) 30, which extends through the field oxide layer 24 and the isolating layer 26 and is connected to the drain region 16, and a source contact (source) 32, which extends through the field oxide layer 24 and the isolating layer 26 and is connected to the source region 14.

A channel region 34 is defined between the source region 14 and the drain region 16. A portion of the surface of the substrate 12 above the channel region 34 is exposed, it is therefore neither covered by the field oxide layer 24 nor by the isolating layer 26. A gate 36 is formed in this exposed region, which is formed of carbon nitride (CNₓ) according to the invention. In a preferred embodiment, the gate 36 has preferably a nitrogen content in a range of 18-30 at %. With these admixtures, both a good adhesion strength on the layers lying below as well as a good chemical resistivity against aggressive chemicals results. The adhesion strength of the gate carbon nitride layer depends on the nitride admixture, wherein the adhesion capability increases with increasing nitride content.

As can be seen in FIG. 1, the FET 10 comprises further isolation layers 38 and 40, which are formed on the drain 30 and the source 32, respectively. In a region, which extends from the drain 30 to the gate 36 and from the source 32 to the gate 36, respectively, a protective layer 42 and 44, respectively, is formed on the isolation layer 38 and 40, respectively, and on the isolating layer 26. The protective layers 42 and 44 protect all regions of the FET 10, apart from the gate 36, from contact with the measurement media. The protective layers 42 and 44 serve for chemical and mechanical protection of the source 32 and the drain 34. The protective layers 42 and 44 are preferably formed of one material, which provides a high chemical and mechanical protection for the FET 10. Since the isolating layers 38, 40 and 26 are arranged between the protective layers 42 and 44, respectively, and the source 32 and the drain 34, respectively, the protective layers 42 and 44, respectively, can also be formed by a conductive material.

Due to the insertion of nitrogen into the gate, the above-described ion sensitive FET has reduced mechanical internal stresses in the gate, whereby an improved adhesion capability is achieved without deterioration of the sensory behavior. The adhesion capability of the gate 36 of carbon nitride is already increased for small admixtures in the doping measure, i.e. in a range starting from 10¹⁴ atoms/cm³, in comparison to a conventional gate of amorphous diamond-like carbon.

Further, the gate 36 of carbon nitride has a high resistance against chemically aggressive substances, which can be adjusted by an appropriate nitrogen doping of the carbon nitride layer, as well as the adhesion capability, so that the ion sensitive FET 10 can be operated in aggressive chemical media, such as hydrofluoric acid, with high resistance. In the same way, the inventive ion sensitive FET is characterized by high long term stability and low drift due to the good resistance of carbon nitride.

Preferably, the inventive ion sensitive field effect transistor is produced in a CMOS process, whereby a cost effective production of the same is enabled. Typically, several ion sensitive field effect transistors are produced in a wafer bond on 150 mm semiconductor wafers. Thereupon, chips, comprising an area of about 4 mm×4 mm, are diced, mounted on boards and electrically contacted. For producing a measurement system, a chip is then transferred into an appropriate construction. Typically, a measurement system, where the ion sensitive field effect transistor is inserted, represents a dip-in sensor, which can, for example, be used for measuring a pH value in industry wastewater.

Preferably, for forming the gate 36, a reactive sputtering of a graphite target is used in a nitrogen atmosphere. Other known deposition methods, which fulfill the requirements of layer quality and homogeneity, can also be used for depositing the gate 36. Examples of appropriate methods comprise evaporation, ablation or plasma enhanced chemical vapor deposition (PECVD).

The nitrogen content is preferably set when forming the gate 36 corresponding to the desired mechanical and/or chemical requirements in an application of the FET in an intended field of application. The nitrogen content can range from small admixtures in the doping range, which are just sufficient to change characteristics of the amorphous diamond-like carbon, up to a stoichiometry of the C₃N₄ or higher.

Further, in other embodiments, the gate 36 can comprise a layer structure with several layers of carbon nitride with different nitrogen content or a layer (gradient layer) with a nitrogen content changing in the direction of the thickness of the layer (y direction in FIG. 1). Thereby, an advantageous behavior is achieved, with a very good adhesion capability and a very good chemical resistance, respectively.

In a gate 36 with a layer structure, a lower layer of the layer structure arranged adjacent to the channel region 44 has a high nitrogen proportion for forming a good adhesion, wherein the nitrogen proportion of the layers decreases with increasing distance of the channel region, so that an outer or, in y direction (see FIG. 1), upper surface of the gate 36, which comes into contact with the measurement medium during operation of the ion sensitive field effect transistor, has a high chemical resistance due to the low nitrogen proportion.

In a further embodiment, the gate 36 comprises a concentration gradient, so that the nitrogen concentration of the gate 36 decreases starting from a surface of the gate adjacent to the channel region 34 with increasing distance there from, so that an outer or in y direction (see FIG. 1) upper surface of the gate 36, which comes into contact with the measurement media during operation of the ion sensitive field effect transistor, has a high chemical resistance due to the low nitrogen proportion.

Additionally, in a preferred embodiment, an intermediate layer can be provided, which, on the one hand, has a good adhesion capability on the silicon substrate 12 and/or the field oxide layer 24, and, on the other hand, a good adhesion capability on the gate layer 28.

In the following, an example for using the inventive ion sensitive field effect transistors will be discussed. In this example, a pH value measurement is performed by using the ion sensitive field effect transistor. A container 46 shown schematically in FIG. 1 contains a measurement fluid 48, such as an aqueous solution, whose pH value is to be measured. As can be seen in FIG. 1, the container 46 is arranged on the ion sensitive FET 10 such that the aqueous solution is in contact with the gate 36. The aqueous solution is separated from the other regions of the FET 10 by layers 42 and 44 as well as the further layers 48 and 50 shown schematically in FIG. 1. A reference electrode 56, which can consist, for example, of Ag, AgCl and KCl, is introduced into the measurement media.

By means of a voltage source 52, which applies an electric voltage U_{DS} between the drain 30 and the source 32, a drain source current I_{DS} is effected. The terminal 28 is connected to a reference potential 54, e.g. ground.

An electric voltage is formed between the reference electrode 56 and the gate 36 due to a different electrochemical voltage valency of the materials of the reference electrode and the gate, which depends on an ion concentration of the measurement media.

In a preferred embodiment, the voltage source 52 is formed to control the drain source voltage, so that always a constant drain source current is flowing. Consequently, in this embodiment, the gate potential is determined and adjusted by the constant drain source current in a changing ion concentration. If the ion concentration of the measurement media changes, the potential of the reference electrode 56 with regard to ground is changing due to the changing electrical voltage between the reference electrode 56 and the gate 36. Thereby, the voltage U_{GS} applied between source and reference electrode 56 is a measurement value, which depends on a ion concentration of the measurement media, whereby the ion concentration of the measurement media can be established by tapping off the voltage U_{GS}.

Although in the above embodiments, merely an FET with a p substrate, n source region and n drain region has been described, the present invention is not limited thereto, but also comprises FETs with n substrate, p source region and p drain region.

While this invention has been described in terms of several preferred embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. An ion sensitive field effect transistor comprising a gate of carbon nitride.

2. The ion sensitive field effect transistor according to claim 1, wherein the gate of carbon nitride has a nitrogen content, which is higher than 10¹⁴ nitrogen atoms/cm³ and lower than or equal to the nitrogen content which corresponds to a stochiometry of C₃N₄.

3. The ion sensitive field effect transistor according to claim 1, wherein the gate has a nitrogen content of 18 at % to 30 at %.

4. The ion sensitive field effect transistor according to claim 1, wherein the gate has a nitrogen content corresponding to a stochiometry of C₃N₄.

5. The ion sensitive field effect transistor according to claim 1, wherein the gate has several stacked layers of carbon nitride, which differ with regard to their nitrogen content.

6. The ion sensitive field effect transistor according to claim 5, wherein the gate is arranged at least partly on the substrate, wherein the nitrogen content of the stacked layers decreases starting from a lowermost layer, which is arranged at least partly on the substrate, with increasing distance in the direction of the thickness of the layer sequence.

7. The ion sensitive field effect transistor according to claim 1, wherein the gate has a carbon nitride layer, whose nitride content changes in the direction of a thickness of the carbon nitride layer.

8. The ion sensitive field effect transistor according to claim 7, wherein the carbon nitride layer is arranged at least partly on a substrate, wherein the nitrogen content of the carbon nitride layer decreases in the direction of the thickness of the layer with increasing distance from the substrate.

9. The ion sensitive field effect transistor according to claim 1, wherein the gate is arranged at least partly on an intermediate layer, wherein the intermediate layer has an adhesion strength both with regard to silicon and with regard to carbon nitride.

10. A method for producing an ion sensitive field effect transistor, comprising:
providing a substrate having a source region and a drain region; and
forming a gate of carbon nitride on the substrate.

11. The method according to claim 10, wherein the step of forming the gate comprises reactive sputtering of a graphite target in a nitrogen atmosphere, an evaporation, an ablation or a chemical vapor deposition.

12. The method according to claim 10, wherein the step of forming a gate comprises:
forming an intermediate layer, which has both an adhesion capability on the substrate and on the carbon nitride; and
forming the carbon nitride layer, which extends at least partly on the intermediate layer.

13. The method according to claim 10, wherein the step of forming a gate comprises the step of forming several carbon nitride layers, which differ with regard to the nitrogen content.

14. The method according to claim 10, wherein the step of forming a gate comprises the step of forming the carbon nitride layer, whose nitrogen content changes in the direction of the thickness of the layer.
